(19) United States
(12) Patent Application Publication
(10) Pub. No.: US 2010/0243165 A1
(43) Pub. Date: Sep. 30, 2010

(54) APPARATUS FOR SURFACE-TREATING WAFER USING HIGH-FREQUENCY INDUCTIVELY-COUPLED PLASMA

(76) Inventor: Pyung-yong Um, Kyungki-do (KR)

Correspondence Address: LADAS & PARRY LLP, 224 SOUTH MICHIGAN AVENUE, SUITE 1600, CHICAGO, IL, 60604, US

(21) Appl. No.: 12/739,222

(22) PCT Filed: Nov. 1, 2007
(86) PCT No.: PCT/KR2007/005484

§ 371 Date: Apr. 22, 2010

(51) Int. Cl. C23F 1/08; C23C 16/00

(52) U.S. Cl. 156/345.34; 156/345.1; 118/723 R; 118/723 I; 156/345.52

(57) ABSTRACT

Disclosed herein is an apparatus for surface-treating a wafer using high-frequency inductively-coupled plasma, including a process chamber including a plasma generation unit into which a reaction gas is introduced and which generates plasma, and a wafer treatment unit in which any one or more selected from among plasma treatment, thin film formation and etching is performed; and a pressure control unit including a vacuum plate, and a pumping port, a two-stage valve, a turbo pump and an APC valve which are organically connected with the vacuum plate, to control a pressure in the process chamber and a pumping rate.

### TECHNICAL FIELD

The present invention relates to a wafer surface treatment apparatus which can be used to plasma-treat a wafer, form a thin film on the wafer and then etch the thin film, using helical type high-frequency inductively-coupled plasma, and more particularly, to an apparatus for surface-treating a wafer using high-frequency inductively-coupled plasma, in which high-frequency inductively-coupled plasma (ICP) using a helical coil with four turns is employed, and thus the efficiency of plasma treatment is increased, in which a plasma source provided in a cylinder prevents plasma from being directly applied on the surface of a wafer, so that the deterioration of device characteristics of a work surface caused by plasma can be prevented, thereby maintaining effective process conditions for oxidation, nitridation, deposition, and etching, and which can prevent a wafer from sliding by embossing an upper surface of a heater cover.

### BACKGROUND ART

Generally, when a coil is wound on a dielectric reactor, such as a quartz reactor or the like, and then an electric field is changed, an induced magnetic field is generated in the coil, and thus a secondary induced current is formed in the dielectric reactor. Inductively-coupled plasma is high-density plasma generated in this way.

Such conventional inductively-coupled plasma is formed using a method of providing an ICP antenna outside a dielectric window and thus indirectly transferring high-frequency power to the dielectric window. This method has a serious problem in that, when electroconductive materials, such as metals, TiN, and the like, are applied on the inner surface of the dielectric windows, none of the high-frequency power is transferred to the dielectric window, and thus plasma cannot be maintained constant.

Therefore, currently, several developed plasma treatment apparatuses are also limitedly used only in dielectric thin film processes etc. Further, they are problematic in that the interior dielectric material must be continuously cleaned for maintenance and in that when the dielectric window is fabricated in a large size, the mechanical strength of the dielectric window may be decreased and there is a difficulty in the maintenance, thus causing the application to the fabrication of a large-sized dielectric window to difficult.

Therefore, in order to overcome the above problems, there is a method of treating a wafer using microwaves as a plasma source. Although this method is advantageous in that the surface of the wafer is not damaged by plasma because the plasma generated during a process is filtered or does not influence the surface thereof, this method is problematic in that since microwaves are used as the plasma source, processes are limitedly applied, and the process window is very small, with the result that it is difficult to maintain process characteristics and increase the production of wafers during a process requiring high skill.

Further, in order to overcome the above problems, there is another method of treating a wafer using a decoupled plasma source, which is conducted by an apparatus using energy of very low eV. This method is problematic in that, even when low energy is used in a process of manufacturing a highly integrated semiconductor device, since plasma directly influences the surface of the wafer during the process, the characteristics of the thin film or the nitride film formed on the wafer are deteriorated due to the plasma damage, which causes physical and chemical imbalance, so that the characteristics of the manufactured semiconductor device are deteriorated and thus the quality thereof is worsened, with the result that this method cannot be used to manufacture a highly integrated semiconductor device.

When LCDs are manufactured using the above methods, an insulation film is widely used to insulate devices. Such an insulation film may be a thin film produced using a method of producing an insulation film using plasma, in which silane is used as a source gas. The insulation film produced using this method is also problematic in that the process window is small, the produced insulation film is locally or entirely damaged, thus causing decrease in the productivity of the insulation film and deterioration of the characteristics thereof.

### DISCLOSURE OF INVENTION

### Technical Problem

Accordingly, the present invention has been made keeping in mind the above problems occurring in the prior art, and the present invention provides an apparatus for surface-treating a wafer using high-frequency inductively-coupled plasma (ICP), which includes a plasma generation unit for generating plasma and a wafer treatment unit for treating a wafer provided under the plasma generation unit which are configured in two stages, in which helical type high-frequency inductively-coupled plasma is generated from an antenna coil formed of a helical coil with four turns, and thus the efficiency of plasma generation is increased, and in which a plasma source provided in a cylinder is vertically applied to the surface of a wafer, thus preventing plasma from being directly applied to the wafer, so that the deterioration of work surface characteristics of a device attributable to plasma can be prevented, thereby maintaining effective process conditions for oxidation, nitridation, deposition, and etching.

Further, the present invention provides an apparatus adapted for plasma treatment, thin film formation and etching using high-frequency inductively-coupled plasma (ICP), which can prevent a wafer from sliding by embossing an upper surface of a heater cover.

### Technical Solution

In an aspect, the present invention provides apparatus for surface-treating a wafer using high-frequency inductively-coupled plasma, including a process chamber including a plasma generation unit into which a reaction gas is introduced and which generates plasma, and a wafer treatment unit in which any one or more selected from among plasma treatment, thin film formation and etching is performed; and a pressure control unit including a vacuum plate, and a pumping port, a two-stage valve, a turbo pump and an APC valve which are organically connected with the vacuum plate, to control a pressure in the process chamber and a pumping rate. The plasma generation unit of the process chamber includes a gas supply pipe, which is provided at the upper end of the plasma generation unit to supply a reaction gas into the plasma generation unit, a cylinder provided in the plasma generation unit, a shower head, which communicates with the gas supply pipe to supply the reaction gas into the cylinder, and an antenna coil, which is wound around the chamber body to generate plasma. The wafer treatment unit of the process chamber includes an inner cover disposed along an inner surface of the process chamber, a heater and a heater cover for heating a wafer, on a center of which a wafer is placed, and a vacuum plate for sealing a lower surface of the wafer treatment unit and controlling the inner pressure in the process chamber.

Further, a diffusion surface having an inclination angle is formed at a periphery of an opening of the wafer treatment unit where the wafer treatment unit communicates with the plasma generation unit such that a reaction gas and a plasma source supplied from the plasma generation unit are uniformly supplied to the wafer treatment unit. A gas distribution plate is further provided on the diffusion surfaces such that a reaction gas and a plasma source supplied from the plasma generation unit are uniformly supplied to the wafer treatment unit. The gas distribution plate is configured in a disk shape, and includes a plurality of long holes radially formed therethrough.

Further, the antenna coil formed in the process chamber is formed of a helical coil with four turns to wind the cylinder such that plasma is generated at high efficiency, and supplies a helical type plasma source. The cylinder formed in the process chamber is formed in a cylindrical shape. Therefore, the antenna coil of the plasma generation unit generates plasma at high efficiency using helical type high-frequency inductively-coupled plasma (ICP). Further, the antenna coil formed of a helical coil with four turns to wind the cylinder is used in order to prevent the deterioration in the characteristics of the wafer, which occurs when the plasma generated on the surface of a wafer is directly influenced by the ICP, and thus the characteristics of the device or thin film are influenced by the plasma, so that the plasma source generated in the cylinder flow down the wafer treatment unit, thereby obtaining a desired wafer. The heater provided in the wafer treatment unit of the process chamber heats a wafer placed thereon to a temperature ranging from room temperature to 700° C. using a single gas or a mixed gas required for oxidation, nitridation, deposition and etching processes in order to form a desired thin film on the surface of the wafer. The shower head, cylinder, gas distribution plate, heater cover, inner cover and vacuum plate, which cover the inner portion of the process chamber, are formed of nonconductive materials.

### ADVANTAGEOUS EFFECTS

As described above, the apparatus for surface-treating a wafer using high-frequency inductively-coupled plasma according to the present invention is advantageous in that in order to treat the surface of a wafer using plasma in oxidation, nitridation, deposition and etching processes, the helical type high-frequency plasma generated from the plasma generation unit is supplied to the wafer treatment unit for treating the wafer together with a reaction gas, thus realizing a process chamber which can be used to easily form a process window.

Further, the apparatus for surface-treating a wafer using high-frequency inductively-coupled plasma according to the present invention is advantageous in that since the components surrounding the process chamber are formed of nonconductive materials, they prevent plasma from being directly applied to the wafer, thus preventing the deterioration in the characteristics of the wafer due to physical and chemical imbalance of the wafer, and in that since diffusion surfaces and a gas distribution plate are formed between the plasma generation unit and the wafer treatment unit, the reaction gas and the plasma source can be uniformly and reproductively supplied to the wafer.

Further, the apparatus for surface-treating a wafer using high-frequency inductively-coupled plasma according to the present invention is advantageous in that since an antenna coil formed of a helical coil is wound around a cylinder of the plasma generation unit four times, and thus high frequency inductively-coupled plasma (ICP) is employed in order to supply high-efficiency helical type plasma and then the wafer placed in the process chamber is heated to a temperature ranging from room temperature to 700° C., the surface of the wafer can be oxidized, nitrided, deposited and etched to form a desired thin film, deterioration in the characteristics of the wafer caused by the plasma generated on the surface of a workpiece during the processes can be prevented, and process conditions can be effectively maintained.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic view showing an apparatus for surface-treating a wafer according to the present invention;

FIG. 2 is a partially enlarged cross-sectional view showing the diffusion surface of a process chamber according to the present invention;

FIG. 3 is a perspective view showing a cylinder according to the present invention, which is partly cut away; and

FIG. 4 is a perspective view showing a gas distribution plate according to an embodiment of the present invention.

### BEST MODE FOR CARRYING OUT THE INVENTION

Hereinafter, the present invention will be described in detail with reference to the attached drawings.

Reference should now be made to the drawings, in which the same reference numerals are used throughout the different drawings to designate the same or similar components.

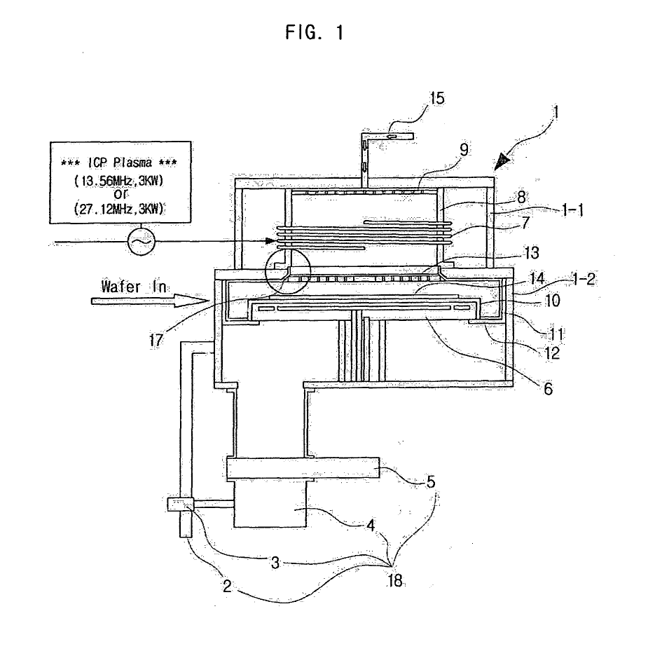

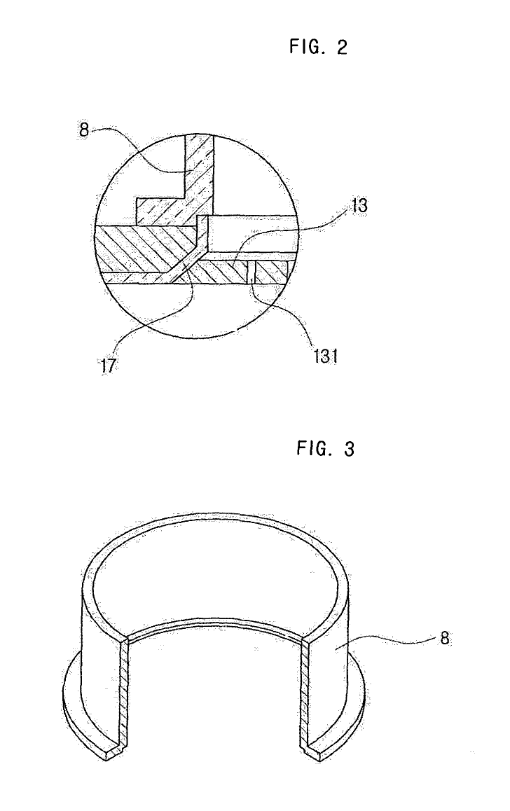

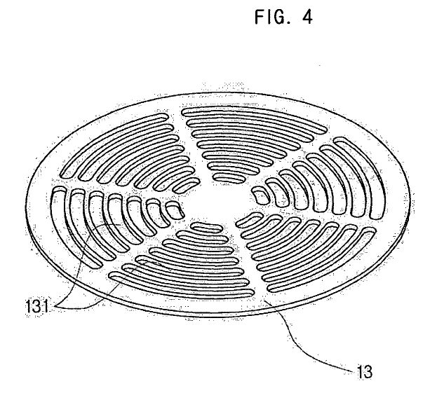

FIG. 1 is a schematic view showing an apparatus for surface-treating a wafer according to the present invention, FIG. 2 is a partially enlarged cross-sectional view showing the diffusion surface of a process chamber according to the present invention, FIG. 3 is a perspective view showing a cylinder according to the present invention, which is partly cut away, and FIG. 4 is a perspective view showing a gas distribution plate according to an embodiment of the present invention.

As shown in FIG. 1, the apparatus for surface-treating a wafer according to the present invention includes a process chamber 1 having a two-stage structure, which includes a plasma generation unit 1-1 located at the upper stage of the process chamber 1, into which a reaction gas is introduced to generate plasma, and a wafer treatment unit 1-2 located at the lower stage of the process chamber 1 for selectively conducting deposition and/or etching of a wafer 14.

In the process chamber 1, since the size of the wafer treatment unit 1-2 is larger than that of the plasma generation unit 1-1, the wafer treatment unit 1-2, that is, a wafer treatment window, can be maximized regardless of the size of the plasma generation unit 1-1.

The apparatus for surface-treating a wafer according to the present invention further includes a pressure control unit 18 for controlling the pressure of the process chamber 1 and the pumping rate thereto, which includes a pumping port 2, a two-stage valve 3, a turbo pump 4, and an APC valve. Here, since such a pressure control unit is a commonly-used device, the description of the pressure control unit will be omitted.

This two stage process chamber 1 is described as follows. In the plasma generation unit 1-1, a gas supply pipe 15 for supplying a single gas or a mixed gas required for the process of oxidation, nitridation, deposition, etching, or the like, which is selected depending on the characteristics of a wafer 14, is formed at the center of the upper end of the plasma generation unit 1-1, and a cylinder 8 is formed in the plasma generation unit 1-1. The cylinder 8 is provided with a shower head 9 at the upper end thereof such that the shower head 9 communicates with the gas supply pipe 15, and is provided with an antenna coil 7 wound therearound, thus generating plasma through the antenna coil 7.

In this regard, the antenna coil 7 formed in the process chamber 1 is wound around the cylinder 8 in the helical shape four times, and thus supplies helical type plasma. The reason why the cylinder formed in the process chamber 1 is formed in the cylindrical shape is that the antenna coil 7 can be wound on the cylinder 8 in a helical shape thus generating high-efficiency high-frequency plasma. The antenna coil 7 is wound around the cylinder 8 in the helical shape multiple times to maximize the efficiency of plasma. Therefore, when plasma of 13.56 MHz or 27.12 MHz is generated using a power of 3 KW, it is preferred that the antenna coil 7 is wound in the helical shape four times, in order to maximize the efficiency of plasma.

The present invention is not limited to this embodiment, and the spirit and scope of the present invention should be construed to cover any processes using all or part of the structure of the process chamber.

In this case, since the essential technical point of the present invention is the process chamber 1, in which plasma is used, the description of the concrete configuration and operation of the associated components of the plasma generation apparatus, which is well known in the art, may be omitted. However, the concrete configuration, operation and effect of the novel antenna coil 7 for generating plasma, which is provided in the process chamber, may pertain to the essential point of the present invention.

Further, since the gas supply pipe 15 is formed in the center of the upper end of the plasma generation unit 1-1, a reaction gas can be uniformly supplied into the sealed process chamber 1. However, in order to more uniformly supply the reaction gas into the process chamber 1, the shower head 9 is formed at the upper end of the cylinder 8 such that the shower head 9 communicates with the gas supply pipe 15.

Meanwhile, the wafer treatment unit 1-2 of the process chamber 1 includes an inner cover 11 disposed along the inner surface of the water treatment unit 1-2, a heater 6 for heating a wafer 14, a heater cover 10 on which the wafer 14 is placed, and a vacuum plate 12 for sealing the lower portion of the wafer treatment unit 1-2 and controlling the pressure in the process chamber 1.

In this case, diffusion surfaces 17, having a proper inclination angle of about 5-85 degrees, and preferably 45 degrees, are formed at a periphery of an opening of the wafer treatment unit 1-2 communicating with the plasma generation unit 1-1 of the process chamber 1 in order to uniformly supply the reaction gas and plasma source, generated in the plasma generation unit 1-1, to the wafer treatment unit 1-2. In order to more uniformly supply the reaction gas and plasma source, generated in the plasma generation unit 1-1, to the wafer treatment unit 1-2, a gas distribution plate 13 may further be provided on the diffusion surfaces 17 (see FIGS. 2 and 3).

Preferably, the gas distribution plate 13, which has a disk shape, includes a plurality of long holes 131 uniformly formed therein, so that the reaction gas and plasma source are uniformly supplied to the wafer 14. The plurality of long holes 131 may be formed parallel to or perpendicular to each other in continuous or intermittent pattern. Further, the gas distribution plate 13 may be formed in rectangular, polygonal or circular shape, and may be formed to be perpendicular to each other in a simple pattern. However, in order to more uniformly supply the reaction gas and plasma source to the wafer 14, it is preferred that the long holes 131 be radially formed about the center of the disk. The above technical idea is only an example of an implementation of the present invention, and the present invention may include other ideas for more uniformly supplying the generated plasma (see FIG. 3).

Such a reaction gas required for process characteristics may be a single gas or a mixed gas of two or more gases. The flow of the reaction gas may be optimized by the shower head 9, communicating with the gas supply pipe 15 located at the center of the top of the cylinder 8, the diffusion surface 17, and the gas distribution plate 13.

This shower head 9, which is adapted to seal the upper end of the cylinder 8, may be configured such that a plurality of downwardly tapered cylindrical through-holes, which are formed through a disk body, is continuously and uniformly distributed parallel to or perpendicular to each other in order to supply the reaction gas supplied from the gas supply pipe 15 into the cylinder 8 (not shown).

Like this, the process chamber 1 includes a plasma generation unit 1-1 and a wafer treatment unit 1-2, which are configured in two stages. Further, the process chamber 1 is sealed to perform a wafer treatment process. In this case, since the characteristics of a wafer 14 may be deteriorated when the wafer 14 is directly influenced by the plasma generated from the plasma generation unit 1-1, the interior components of the process chamber 1 surrounding the wafer 14, that is a shower head 9, a cylinder 8, a gas distribution plate 13, a heater cover 10, a process chamber inner cover 11, and a vacuum plate, may be formed of nonconductive materials. The reason for forming the interior components from the nonconductive materials is that if the interior components are made of conductive materials, the conductive constituents of the interior components may adhere to the plasma-generating portion of the plasma generation unit during the wafer treatment process, thus preventing the continuous generation of the plasma due to interruption of power transfer to the antenna coil.

In this case, although it is most preferable that the interior components of the process chamber 1 are made of qualtz, the interior components of the process chamber 1 may be selectively made of various nonconductive materials depending on the characteristics of the processes of oxidation, nitridation, deposition and etching.

In this way, the cylinder 8 and shower head 9 of the plasma generation unit 1-1 are formed of nonconductive materials such that the wafer 14 is not damaged by the plasma source supplied from the plasma generation unit 1-1, and the gas distribution plate 13, heater cover 10, process chamber inner cover 11 and vacuum plate 12 of the wafer treatment unit 1-2, which surround the wafer 14, are also formed of non-conductive materials, so that the problem, occurring when the plasma generated from the antenna coil 7 is directly applied to the wafer 14, can be overcome because the interior of the process chamber 1 is surrounded with the interior components formed of nonconductive materials, and the contamination in the process chamber can be prevented because the interior components are formed of materials which do not react with plasma.

As described above, the process chamber 1 is provided with the plasma generation unit 1-1 for generating plasma and supplying a reaction gas and the wafer treatment unit 1-2, on which a wafer 14 is placed, for applying proper pressure and temperature to the wafer 14 in two stages. In the wafer treatment process, it is preferred that the wafer 14 be heated to a temperature ranging from room temperature to 700° C. using a heater 6.

The operation of the wafer surface treatment apparatus is described as follows.

A plasma source is generated from an antenna coil 7 wound around a cylinder 8 provided in a plasma generation unit 1-1, and a reaction gas supplied from a gas supply pipe 15 is uniformly supplied to the cylinder 8 through a shower head 9. Then, the plasma source and the reaction gas supplied to the cylinder 8 are supplied from the plasma generation unit 1-1 to a wafer treatment unit 1-2. In this case, the plasma source and reaction gas are uniformly supplied to a wafer 14 through a diffusion surface 17 and a gas distribution plate 13, which are provided between the plasma generation unit 1-1 and the wafer treatment unit 1-2. The reason for providing the diffusion surface 17 and the gas distribution plate 13 is that, if there are no these components, the density of the plasma and the reaction gas applied to the surface of the wafer 14 are not entirely uniform, and thus the plasma processing rate, such as the etching rate, the thin film formation rate, and the like, changes, thus hindering a wafer having a desired etching depth or thin film depth from being obtained after a pre-determined time has passed. That is, if the diffusion plate 17 and the gas distribution plate 13 are not provided, the characteristics of the resulting wafer are deteriorated.

When this plasma and reaction gas are uniformly supplied onto the wafer 14 through the gas distribution plate 13, the wafer is heated to a temperature ranging from room temperature to 700° C. using a heater 6 and a heater cover 10, thus forming a desired thin film on the wafer 14.

Accordingly, the present invention provides an apparatus for generating high efficiency helical type plasma and surface-treating a wafer using the plasma, in which the plasma is high-frequency inductively-coupled plasma (ICP) generated from an antenna coil 7 formed of a helical coil with four turns, and a single gas or a mixed gas is used in the processes of oxidation, nitridation, deposition and etching. Further, the present invention provides an apparatus for forming a thin film and etching the thin film using the high frequency inductively-coupled plasma, in which the surface of a workpiece is not directly influenced by the plasma, so that the deterioration of characteristics of the treated wafer, which is caused by the damage generated from the plasma, is prevented, and thus effective process conditions can be maintained, and excellent process characteristics can be obtained.

For example, a process of forming a thermally-oxidized film or a thermally-nitrided film according to the present invention is performed by generating plasma having a frequency of 13.56 MHz or 27.12 MHz using a power of 1˜5 KW supplied to an antenna and selecting one from among process gases, such as O2, N2, NH3, Ar, H2 and the like, depending on the use thereof, in each process.

That is, the present invention provides a wafer surface treatment apparatus in which the wafer 14 is heated to a temperature ranging from room temperature to 700° C., and is then exposed to high-density plasma, thus forming a desired type thin film, and in which the thin film is oxidized, nitrided, deposited and etched using the plasma.

As described above, the present invention provides a wafer surface treatment apparatus including a plasma generation unit and a wafer treatment unit.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. An apparatus for surface-treating a wafer using high-frequency inductively-coupled plasma, comprising:
a process chamber including a plasma generation unit into which a reaction gas is introduced and which generates plasma, and a wafer treatment unit in which any one or more selected from among plasma treatment, thin film formation and etching is performed; and
a pressure control unit including a vacuum plate, and a pumping port, a two-stage valve, a turbo pump and an APC valve which are organically connected with the vacuum plate, to control a pressure in the process chamber and a pumping rate.

2. The apparatus for surface-treating a wafer using high-frequency inductively-coupled plasma according to claim 1, wherein the plasma generation unit of the process chamber comprises a gas supply pipe, which is provided at the upper end of the plasma generation unit to supply a reaction gas into the plasma generation unit, a chamber body provided in the plasma generation unit, a shower head, which communicates with the gas supply pipe to supply the reaction gas into the chamber body, and an antenna coil, which is wound around the chamber body to generate plasma.

3. The apparatus for surface-treating a wafer using high-frequency inductively-coupled plasma according to claim 1, wherein the wafer treatment unit of the process chamber comprises an inner cover disposed along an inner surface of the process chamber, a heater and a heater cover for heating a wafer, on a center of which a wafer is placed, and a vacuum plate for sealing a lower surface of the wafer treatment unit and controlling the inner pressure in the process chamber.

4. The apparatus for surface-treating a wafer using high-frequency inductively-coupled plasma according to claim 1, wherein a diffusion surface having an inclination angle is formed at a periphery of an opening of the wafer treatment unit where the wafer treatment unit communicates with the plasma generation unit such that a reaction gas and a plasma source supplied from the plasma generation unit are uniformly supplied to the wafer treatment unit.

5. The apparatus for surface-treating a wafer using high-frequency inductively-coupled plasma according to claim 1 or 4, wherein a gas distribution plate is further provided on the diffusion surfaces such that a reaction gas and a plasma source supplied from the plasma generation unit are uniformly supplied to the wafer treatment unit.

6. The apparatus for surface-treating a wafer using high-frequency inductively-coupled plasma according to claim 5, wherein the gas distribution plate is configured in a disk shape, and includes a plurality of long holes formed therethrough.

7. The apparatus for surface-treating a wafer using high-frequency inductively-coupled plasma according to claim 1 or 2, wherein the antenna coil provided in the process chamber is formed of a helical coil wound on the chamber body four times, and supplies a helical type plasma source.

8. The apparatus for surface-treating a wafer using high-frequency inductively-coupled plasma according to claim 1 or 2, wherein the chamber body provided in the process chamber is formed in a cylindrical shape.

9. The apparatus for surface-treating a wafer using high-frequency inductively-coupled plasma according to claim 1 or 3, wherein the heater provided in the wafer treatment unit of the process chamber heats a wafer placed thereon to a temperature ranging from room temperature to 700° C.

10. The apparatus for surface-treating a wafer using high-frequency inductively-coupled plasma according to any one of claims 1 to 3, wherein the shower head, the chamber body, the gas distribution plate, the heater cover, the inner cover and the vacuum plate, which surround an interior of the process chamber, are formed of nonconductive materials.
